(19) United States
(12) Patent Application Publication
(10) Pub. No.: US 2020/0099335 A1
(43) Pub. Date: Mar. 26, 2020

(54) A MOBILE LABORATORY FOR TESTING PHOTOVOLTAIC (PV) MODULES

(71) Applicant: MAHINDRA SUSTEN PVT. LTD., Maharashtra (IN)

(72) Inventors: Satish PANDEY, Maharashtra (IN); Abhay TILWANKAR, Maharashtra (IN); Mayank SHAH, Maharashtra (IN)

(21) Appl. No.: 16/614,417

(22) PCT Filed: May 16, 2018
(86) PCT No.: PCT/IB2018/053418

§ 371 Date: Nov. 18, 2019

(30) Foreign Application Priority Data
May 17, 2017 (IN) 201721017370

(51) Int. Cl. H02S 50/15; G01R 31/308; G01S 19/01

(52) U.S. Cl. CPC H02S 50/15; H04B 1/02; G01S 19/01; G01R 31/308

(57) ABSTRACT

The present disclosure relates to a mobile laboratory 100 for testing photovoltaic (PV) modules. In accordance with the present disclosure, the mobile laboratory 100 comprises an enclosure 102, a testing unit 108, a GPS unit 120 and a power supply unit 104. The enclosure 102 is configured to provide a controlled environment for testing of PV modules with the help of an air conditioning unit 106. The GPS unit 120 is configured to identify the location of the PV modules being tested and is further configured to transmit location information to the testing unit 108. The testing unit 108 is configured to test a plurality of parameters associated with the PV modules and, generate an evaluation report based on the tested plurality of parameters in order to assess operational viability of the PV modules.

### FIELD

The present disclosure relates to the field of testing of photovoltaic (PV) modules.

### DEFINITIONS OF TERMS USED IN THE SPECIFICATION

The expression ‘electroluminescence imaging’ used hereinafter in this specification refers to an imaging technique used for detecting a multitude of defects in PV modules. In this method, damaged areas of the PV module appear dark or shine less in an image as compared to good/undamaged areas.

The expression ‘IR Thermography’ used hereinafter in this specification refers to an equipment or method which detects hot spot in an object, in terms of temperature delta.

The expression ‘Flash Testing’ used hereinafter in this specification refers to a technique used to measure the electrical output while simulating the Standard test conditions (STC) for a PV module i.e. 25 Degree Celsius and 1000 W/m2. In this method a sun like flash is focused onto the module which results in the module releasing power which then gets measured in the electronic unit along with the other parameters governing the test. If the output of the module is higher than the rated or guaranteed value then it is deemed as Passed or else as a Defective/Failed module.

These definitions are in addition to those expressed in the art.

### BACKGROUND

Typically, PV modules are fragile as they consist of photovoltaic (PV) cells placed under glass. These PV modules are generally tested and certified before dispatch from the PV Module OEMs factory. Once tested and certified, they are packaged and shipped to the site location for installation, i.e., as a part of a Solar PV power plant. Typically, for a Poly-crystalline module, due to inherent chemical and physical properties of the material, the power output from the PV modules degrade or reduce over a period of time. Generally, around 2.5% reduction in power output is observed in the first year due to LID (Light induced degradation) and another 0.7% reduction year on year for its life of around 25 years. In an event of higher degradation in the power output, the defective PV modules are replaced with a new PV module under the warranty scheme of the product. To identify the degradation these PV modules are generally required to be tested prior to their warranty claim. In order to test the PV modules, they are transported to certified laboratories, which are usually located in only few major cities of a country or a region. Additionally, there is a major risk of module breakages during transportation to laboratories. Further, an accurate method is not available for detailed and in-situ testing of the PV modules. The conventional method of testing is arduous and time consuming as the PV modules are required to be dismounted, packed carefully and transported to the laboratories for testing. Moreover, the conventional method of testing of the PV modules in these stationary laboratories is expensive as it involves module removal cost, packaging cost, and transportation cost in addition to the cost of testing.

An additional aspect which makes this conventional method cumbersome is the limited sample size, typically a MW of Solar consists of 3076 PV Modules. For example, India currently has 20 GW installed with a Target to install around 100 GW by the year 2022, i.e. around 3076 Crore PV Modules scattered across Thousands of locations. Therefore, in order to reduce cost and effort, since it is not possible to dismantle and transport all the modules for testing, typically a small sample of 10-20 modules is taken and shipped, which is not a good statistical number. For a 50 MW module with 1.53 Lakhs PV modules a sample of 20 modules is 0.00013% sample size, which by any means is insignificant.

There is, therefore, felt a need for a mobile laboratory for testing PV modules which facilitate efficient testing of the PV modules at the site location itself thereby alleviating all the aforementioned drawbacks.

### OBJECTS

Some of the objects of the present disclosure, which at least one embodiment herein satisfies, are as follows:

The object of the present disclosure is to ameliorate one or more problems of the prior art or to at least provide a useful alternative.

An object of the present disclosure is to provide a mobile laboratory for testing PV modules.

Another object of the present disclosure is to provide a mobile laboratory which facilitates testing of PV modules at plant sites.

Further, an object of the present disclosure is to provide a mobile laboratory which eliminates the requirement of transporting PV modules for testing.

Furthermore, an object of the present disclosure is to provide a mobile laboratory which can be used for testing PV modules before and after installation on site.

Another object of the present disclosure is to provide a mobile laboratory which enables periodic testing and performance recording of installed PV modules.

Further, an object of the present disclosure is to provide a mobile laboratory which requires minimal set-up time as there are no moving parts and the physical dark room for the testing PV modules is pre-built this avoids any need for calibration or waste in time to create a dark room or adjust any dimensions first.

Furthermore, an object of the present disclosure is to provide a mobile laboratory which can allow report preparation 24×7, also allowing a backup operator to sleep and live inside the Truck.

Another object of the present disclosure is to provide a mobile laboratory which enables self-powered movement since the lab is mounted on the chassis of the truck it does not depend upon another vehicle or support truck to pull it.

Further, an object of the present disclosure is to provide a mobile laboratory which is self-sufficient in terms of the power requirement on account of the in-built Diesel generator for powering the Test set-up and air-conditioner for maintaining the test conditions.

Furthermore, an object of the present disclosure is to provide a mobile laboratory which is unique and allows higher sampling rate at site, with reducing cost as the sample rate increases unlike other labs where an increase in sample will lead to an increase in cost, since the majority cost is the movement of the Lab and logistics expenses.

Another object of the present disclosure is to provide a mobile laboratory which records automatically the GPS location of the PV Modules being tested and eliminates any manual error in relation to recording the location of the testing.

Other objects and advantages of the present disclosure will be more apparent from the following description, which is not intended to limit the scope of the present disclosure.

### SUMMARY

The present disclosure envisages a mobile laboratory for testing photovoltaic (PV) modules. The mobile laboratory comprises an enclosure, a testing unit, a GPS unit, and a power supply unit. The enclosure (also referred to as “Dark room”) is mounted on a chassis of a vehicle. The enclosure is configured to provide a controlled environment for testing the PV modules. The testing unit is provided within the enclosure. The testing unit is coupled to the PV modules, and is configured to test a plurality of parameters associated with the PV modules. Further, the testing unit is configured to generate an evaluation report of the PV modules being tested based on the plurality of parameters in order to assess operational viability of the PV modules. The GPS unit is also provided within the enclosure. The GPS unit is configured to identify the location of the PV modules being tested, and is further configured to transmit the location information to the testing unit. The power supply unit is provided within the enclosure, and is configured to provide uniform power to the testing unit to enable the testing unit to perform testing of the PV modules. In an embodiment, the testing unit includes a memory, a processor, a flash tester/sun simulator, a comparator, an electroluminescence tester, an infrared thermography unit, and an evaluation unit. The memory is configured to store pre-determined rules and reference data. The memory is further configured to store the location information received from the GPS unit. The processor is configured to cooperate with the memory to receive and process the pre-determined rules to generate a set of system operating commands. The flash tester/sun simulator is configured to measure power, voltage, current (PVI) characteristics of the PV modules as per applicable standard. The comparator, under the set of system operating commands, is configured to receive the measured PVI characteristics from the flash tester/sun simulator and the reference data from the memory. The comparator is further configured to compare the measured PVI characteristics with the reference data to generate a compared value. The electroluminescence tester is configured to capture at least one image of the PV modules, and is further configured to detect structural defects on the PV modules based on at least one captured image. The infrared (IR) thermography unit is configured to capture at least one IR image of the PV modules and is further configured to identify defective cells within the PV modules based on at least one captured IR image. The evaluation unit, under the set of system operating commands, is configured to receive the compared value, detected structural defects, and identified defective cells from the comparator, the electroluminescence tester and the infrared thermography unit respectively. The evaluation module is further configured to generate the evaluation report of the tested PV modules based on the received compared value, detected structural defects, and identified defective cells, thereby assessing the operational viability of the PV modules.

In another embodiment, the testing unit is configured to provide the generated evaluation report and the location information associated with the PV modules being tested to a remote server, via a communication unit.

In yet another embodiment, the electroluminescence tester includes at least one high resolution camera that is configured to capture the images of the PV modules being tested.

In still another embodiment, the structural defects of the PV modules are cracks, micro-cracks, potential-induced degradation (PID), and broken fingers in the front metallization.

In an embodiment, the infrared thermography unit includes at least one infrared camera that is configured to capture the IR images of the PV modules being tested.

In another embodiment, the mobile laboratory includes an air conditioning unit which is configured to condition the air within the enclosure to provide a controlled environment for testing the PV modules as per standard testing condition.

In yet another embodiment, the plurality of parameters associated with the PV modules being tested, by the testing unit, are selected from the group consisting of power output determination, electroluminescence imaging and infrared (IR) thermography of the PV modules.

In still another embodiment, the mobile laboratory is configured to perform multi-stage testing of said PV modules, wherein multi-stage testing includes pre-installation testing, post-installation testing and end of life phase testing of the PV modules.

In an embodiment, the GPS unit is configured to periodically transmit current location information of the mobile laboratory to a remote device via the communication module.

### BRIEF DESCRIPTION OF THE ACCOMPANYING DRAWING

A mobile laboratory for testing photovoltaic (PV) modules of the present disclosure will now be described with the help of the accompanying drawing, in which:

FIG. 1 illustrates a block diagram of a mobile laboratory for testing photovoltaic (PV) modules;

FIG. 2 illustrates a pictorial view of a mobile laboratory for testing PV modules;

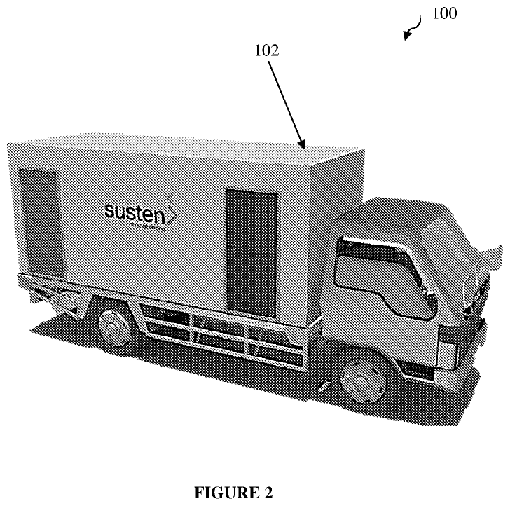

FIG. 3 illustrates a top view of an enclosure of the mobile laboratory of FIG. 2; and

FIG. 4 illustrates a side view of the enclosure of the mobile laboratory of FIG. 2.

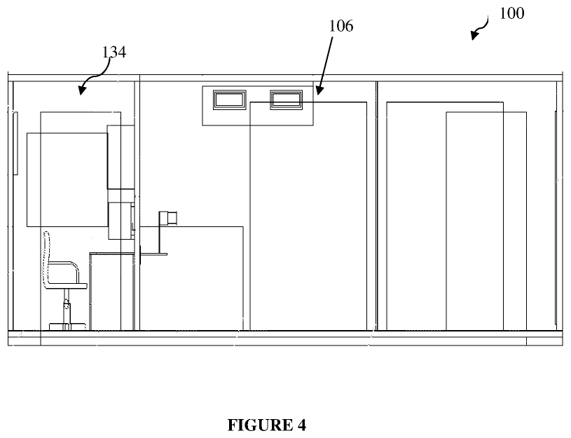

### LIST OF REFERENCE NUMERALS

100—Mobile Laboratory
102—Enclosure
104—Power Supply Unit
106—Air Conditioning Unit
108—Testing Unit
110—Memory
112—Processor
113—Comparator
114—Flash Tester/Sun Simulator
116—Electroluminescence Tester
117—Evaluation Unit
118—Infrared Thermography Unit
120—GPS Unit
122—Communication Unit
124—Display Unit
126—Remote Server
128—Database
130—Remote Device
132—Fire Extinguisher
134—Operator's cabin

### DETAILED DESCRIPTION

A mobile laboratory for testing photovoltaic (PV) modules will now be described with reference to the embodiment shown in the accompanying drawing.

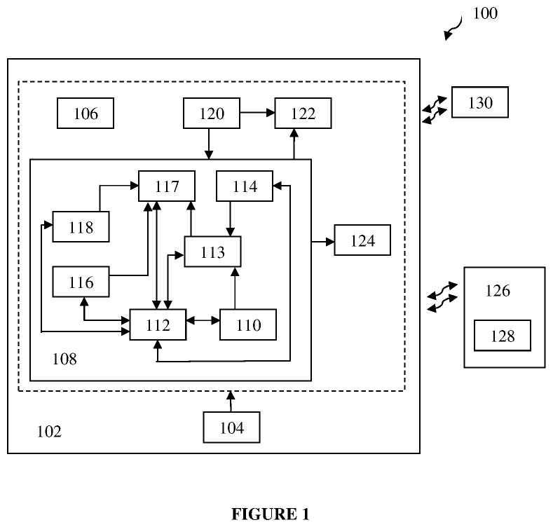

FIG. 1 illustrates a block diagram of a mobile laboratory 100 for testing photovoltaic (PV) modules. The mobile laboratory 100 for testing PV modules comprises an enclosure 102, an air conditioning unit 106, a testing unit 108, a power supply unit 104, a GPS unit 120, and a communication unit 122. The enclosure 102 is configured to provide a controlled environment for testing the PV modules, and is mounted on a chassis of a vehicle. In an embodiment, the air conditioning unit 106 is configured to condition the air within the enclosure 102 to facilitate testing of the PV modules in the controlled environment. In another embodiment, the controlled environment includes Irradiation flash of 1000 W/M2 and a temperature of 25 Degrees Celsius recreated in the mobile laboratory 100 for the testing of the PV modules. In still another embodiment, dimensions of the enclosure 102 are as follows: length=6000 mm, width=2400 mm, and height=2600 mm.

In an embodiment, the mobile laboratory 100 includes an operator's cabin 134 which includes a bunk bed and a workstation which facilitates the operator to conduct test and prepare reports 24×7. Additionally, the operator's cabin also provides accommodation to a back-up operator.

The mobile laboratory 100 is equipped with both on-grid & diesel generator for dual-mode operation. The power supply unit 104 is provided within the enclosure 102. The power supply unit 104 is configured to provide uniform power to the testing unit 108 to enable the testing unit 108 to perform testing of the PV modules. In an embodiment, the power supply unit 104 is an uninterruptible power source (UPS). In another embodiment, the power supply unit 104 acts as a backup supply in case of power loss.

The GPS unit 120 is provided within the enclosure 102. The GPS unit 120 is configured to cooperate with the testing unit 108. The GPS unit 120 is configured to identify the location of PV modules being tested, and is further configured to transmit the location information to the testing unit 108. The GPS unit 120 is also configured to track the location of the mobile laboratory 100, instantly or when it is in motion, and further configured to periodically transmit the current location information of the mobile laboratory 100 to a remote device 130, via the communication unit 122. In an embodiment, the remote device 130 is selected from the group consisting of a mobile device, a handheld device, a laptop, a desktop, a personal digital assistant, a palmtop, a tablet and the like, having communication capabilities. In an embodiment, the GPS unit 120 includes a GPS sensor.

The testing unit 108 is provided within the enclosure 102. The testing unit is coupled to the PV modules to test a plurality of parameters associated with the PV modules in order to assess operational viability of the PV modules. In an embodiment, the plurality of parameters associated with the PV modules is power output determination, electroluminescence imaging and infrared (IR) thermography. The testing unit 108 includes a memory 110, a processor 112, a flash tester/sun simulator 114, a comparator 113, an electroluminescence tester 116, an infrared thermography unit 118 and an evaluation unit 117.

The memory 110 is configured to store a set of pre-determined rules and reference data. The memory 110 is also configured to store received location information of the PV modules being tested, from the GPS unit 120. The processor 112 is configured to cooperate with the memory 110 to receive and process the set of pre-determined rules to obtain a set of system operating commands. The processor 112 may be implemented as one or more microprocessors, microcomputers, microcontrollers, digital signal processors, central processing units, state machines, logic circuitries, and/or any device that manipulates signals based on operational instructions. Among other capabilities, the processor 112 is configured to fetch and execute the set of predetermined rules stored in the memory 110 to control modules/units of the testing unit 108.

The flash tester/sun simulator 114 is solar simulation device that provides illumination similar to natural sunlight. In an embodiment, the flash tester/sun simulator 114 is used for the testing of solar cells, sun screen, plastics, and other materials and devices. The flash tester/sun simulator 114 is configured to measure power, voltage, current (PVI) characteristics of PV modules being tested. In an embodiment, the PVI characteristics of the PV modules are short circuit current (I_{sc}), maximum current (Iₘₐₓ), open circuit voltage (V_{oc}), maximum voltage (Vₘₐₓ), maximum power (Pₘₐₓ), fill factor (FF), and efficiency of the PV modules, temperature coefficient of electrical parameters, efficiency of the PV modules. In an embodiment, the sun simulator selected for testing the PV modules is a Class AAA Tunnel Type Flash tester as per IEC-60904-9.

The comparator 113 is configured to cooperate with the memory 110 and the flash tester/sun simulator 114. The comparator 113, under the set of system operating commands, is configured to receive the measured PVI characteristics from the flash tester/sun simulator 114 and the reference data from the memory 110. The comparator 113, under the set of system operating commands, is configured to compare the measured PVI characteristics with the reference data/Module, and is further configured to generate at least one compared value.

The electroluminescence tester 116 is used for electroluminescence testing. The electroluminescence tester 116 includes at least one high resolution cameras. The high resolution camera is configured to capture images of the cells of a PV module being tested. The electroluminescence tester 116 is further configured to detect structural defects in the cells of the PV module based on at least one captured image of the PV module. In an embodiment, the structural defects are cracks, micro-cracks, potential-induced degradation (PID), and broken fingers in the front metallization of the PV modules.

The IR thermography unit 118 includes at least one infrared (IR) camera to capture IR images of the cells of PV modules being tested. Further, the infrared thermography unit 118 is configured to identify defective cells/part within the PV modules based on at least one captured IR image. In an embodiment, the infrared thermography unit 118 is used to perform IR inspection/thermography on the PV modules with the help of IR camera when the PV modules are in operation.

The evaluation unit 117 is configured to cooperate with the comparator 113, the electroluminescence tester 116 and the IR thermography unit 118. The evaluation unit 117, under the set of system operating commands, is configured to receive detected structural defects from the electroluminescence tester 116, and identified defective cells from the IR thermography unit 118. The evaluation unit 117, under the set of system operating commands, is also configured to receive the compared value from the comparator 113. Further, the evaluation unit 117 is configured to generate an evaluation report of the PV modules being tested based on the detected structural defects, identified defective cells and the compared value, thereby assessing the operational viability of the PV modules. In an embodiment, the evaluation unit 117 is configured to display the evaluation report to a tester/operator via a display unit 124.

Further, the testing unit (108) is configured to transmit the generated evaluation report and the location information associated with the PV modules being tested to the communication unit 122. The communication unit 122 cooperates with a remote server 126 and transmits the generated evaluation report and the location information of the tested PV modules to the remote server 126. The remote server 126 is further configured to store the received evaluation report and the location information of the tested PV modules in a database 128.

In an embodiment, the mobile laboratory 100 is configured to perform multi-stage testing of the PV modules. The multi-stage testing includes three testing: Pre-Installation testing, Post-Installation testing, and End of Life phase testing. At the pre-installation testing, newly arrived PV modules from the module manufacturer are tested before installation at a plant site in order to test if they are working properly. In the post-installation testing, damage to the PV modules during installation is identified. The post-installation testing is a periodic test which may be initially done within one month of installation and then periodically per annum as per the requirement. At the end of life testing, it is identified if the PV modules need to remove or dismantled.

In an embodiment, the mobile laboratory 100 facilitates periodic/routine testing and performance recording of the installed PV modules across their lifetime. The PV modules which are within warranty period can also be replaced if found damaged during their periodic/routine testing at plant site using the mobile laboratory 100. In one embodiment, the mobile laboratory 100 is useful in PV testing for EPC, owners, PV Module Supplier, PV Module Manufactures and Operations & Maintenance (O&M), and Audit teams of a PV Plant. In another embodiment, testing the PV modules using the mobile laboratory 100 also helps in degradation analysis of PV modules.

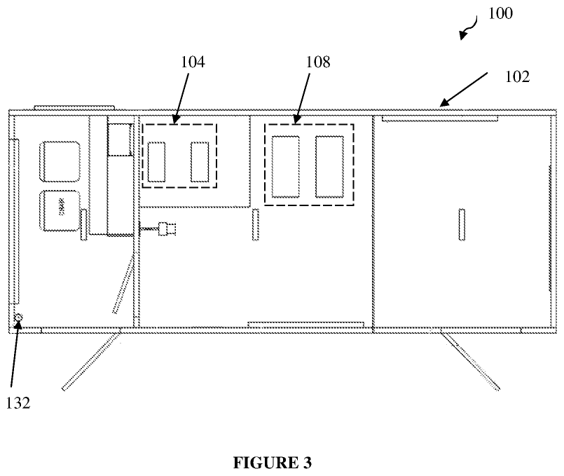

The mobile laboratory 100 also includes a fire extinguisher (shown in FIG. 3) to mitigate the risk of fire within the mobile laboratory 100. In one embodiment, the fire extinguisher is placed in the workstation section of the mobile laboratory 100.

In one embodiment, the mobile laboratory 100 achieves similar or higher quality of tests as that of a stationary laboratory. The mobile laboratory 100 ensures repeatability and reliability of tests on-site, and provides ease and safety of movement even to remote site locations. In another embodiment, the mobile PV laboratory 100 also comprises other components essential for testing of PV modules, includes flash generator(s), temperature panel(s), table(s) and chair(s), rack(s) for various modules, fixing plate(s), sleeping seat(s), recliners, and the like.

### TECHNICAL ADVANCEMENTS

The present disclosure described herein above has several technical advantages including, but not limited to, the realization of a mobile laboratory for testing PV modules that:
facilitates testing of PV modules directly at plant sites;
eliminates the need of removing and transporting PV modules for testing;
can be used for testing PV modules before installation;
enables periodic testing and performance recording of installed PV modules;
provides higher sampling percentage of in-situ tested modules;
reduces the risk of breakage of PV modules along with cost savings and also results in reduced effort;
is useful for warranty claim of under-performing or fatigued PV modules;
is fail safe;
is compatible with all types of Solar module technologies;
requires less time for test analysis and report generation;
does not require any setup time for preparing dark room;
provides an integrated living space for an operator for round the clock work and reporting on the move;
is self-powered and eliminates the need of on-site auxiliary power supply; and
is robust and compact.

The disclosure has been described with reference to the accompanying embodiments which do not limit the scope and ambit of the disclosure. The description provided is purely by way of example and illustration.

The embodiments herein above and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments so fully revealed the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the disclosure to achieve one or more of the desired objects or results.

Any discussion of documents, acts, materials, devices, articles or the like that has been included in this specification is solely for the purpose of providing a context for the disclosure. It is not to be taken as an admission that any or all of these matters form a part of the prior art base or were common general knowledge in the field relevant to the disclosure as it existed anywhere before the priority date of this application.

The numerical values mentioned for the various physical parameters, dimensions or quantities are only approximations and it is envisaged that the values higher/lower than the numerical values assigned to the parameters, dimensions or quantities fall within the scope of the disclosure, unless there is a statement in the specification, specific to the contrary.

While considerable emphasis has been placed herein on the components and component parts of the preferred embodiments, it will be appreciated that many embodiments can be made and that many changes can be made in the preferred embodiments without departing from the principles of the disclosure. These and other changes in the preferred embodiment as well as other embodiments of the disclosure will be apparent to those skilled in the art from the disclosure herein, whereby it is to be distinctly understood that the foregoing descriptive matter is to be interpreted merely as illustrative of the disclosure and not as a limitation.

1. A mobile laboratory (100) for testing photovoltaic (PV) modules, said mobile laboratory (100) comprising:
an enclosure (102) mounted on a chassis of a vehicle, said enclosure (102) configured to provide a controlled environment for testing said PV modules;
a testing unit (108) provided within said enclosure (102), said testing unit (108) coupled to said PV modules, and configured to test a plurality of parameters associated with said PV modules, said testing unit (108) further configured to generate an evaluation report of said tested PV modules based on said plurality of parameters to assess operational viability of said tested PV modules;
a GPS unit (120) provided within said enclosure (102), said GPS unit (120) configured to identify the location of said PV modules being tested, and further configured to transmit the location information to said testing unit (108); and
a power supply unit (104) provided within said enclosure (102), said power supply unit (104) configured to provide uniform power to said testing unit (108) to enable said testing unit (108) to perform testing of said PV modules.

2. The mobile laboratory (100) as claimed in claim 1, wherein said testing unit (108) includes:
a memory (110) configured to store pre-determined rules and reference data, said memory (110) is further configured to store said location information received from said GPS unit (120);
a processor (112) configured to cooperate with said memory (110) to receive and process said pre-determined rules to generate a set of system operating commands;
a flash tester/sun simulator (114) configured to measure power, voltage current (PVI) characteristics of said PV modules;
a comparator (113), under the set of system operating commands, configured to receive said measured PVI characteristics from said flash tester/sun simulator (114) and said reference data from said memory (110), said comparator (113) is further configured to compare said measured PVI characteristics with said reference data to generate a compared value;
an electroluminescence tester (116) configured to capture at least one image of said PV modules, and is further configured to detect structural defects on said PV modules based on at least one captured image;
an infrared thermography unit (118) configured to capture at least one IR image of said PV modules and is further configured to identify defective cells within said PV modules based on at least one captured IR image; and
an evaluation unit (117), under the set of system operating commands, configured to receive said compared value, detected structural defects, and identified defective cells from said comparator (113), said electroluminescence tester (116) and said infrared thermography unit (118) respectively, said evaluation unit (117) is further configured to generate said evaluation report of said tested PV modules based on said compared value, detected structural defects, and identified defective cells, thereby assessing the operational viability of the PV modules.

3. The mobile laboratory (100) as claimed in claim 1, wherein said testing unit (108) is configured to provide said generated evaluation report and said location information associated with said PV modules being tested to a remote server (126), via a communication unit (122).

4. The mobile laboratory (100) as claimed in claim 2, wherein said electroluminescence tester (116) includes at least one high resolution camera configured to capture the images of said PV modules being tested.

5. The mobile laboratory (100) as claimed in claim 2, wherein said structural defects of said PV modules are cracks, micro-cracks, potential-induced degradation (PID), and broken fingers in the front metallization.

6. The mobile laboratory (100) as claimed in claim 2, wherein said infrared thermography unit (118) includes at least one infrared camera configured to capture the IR images of said PV modules being tested.

7. The mobile laboratory (100) as claimed in claim 1, which includes an air conditioning unit (106), configured to condition the air within said enclosure (102) to provide controlled environment for testing said PV modules.

8. The mobile laboratory (100) as claimed in claim 1, wherein said plurality of parameters associated with said PV modules tested by testing unit (108) are selected from the group consisting of power output determination, electroluminescence imaging and infrared (IR) thermography of said PV modules.

9. The mobile laboratory (100) as claimed in claim 1, wherein said mobile laboratory (100) is configured to perform multi-stage testing of said PV modules, wherein multi-stage testing includes pre-installation testing, post-installation testing and end of life phase testing of said PV modules.

10. The mobile laboratory (100) as claimed in claim 1, wherein said GPS unit (120) is configured to periodically transmits current location information of said mobile laboratory (100) to a remote device (130) via said communication module (122).
